(19) United States
(12) Patent Application Publication
(10) Pub. No.: US 2020/0012160 A1
(43) Pub. Date: Jan. 9, 2020

(54) DISPLAY PANEL

(71) Applicant: HKC Corporation Limited, Shenzhen City, Guangdong (CN)

(72) Inventor: Huailiang HE, Shenzhen City, Guangdong (CN)

(21) Appl. No.: 16/328,952

(22) PCT Filed: Dec. 20, 2017
(86) PCT No.: PCT/CN2017/117338

§ 371 Date: Feb. 27, 2019

(30) Foreign Application Priority Data
Aug. 28, 2017 (CN) 201721085208.3

(51) Int. Cl. G02F 1/1362; H01L 27/12

(52) U.S. Cl. CPC G02F 1/136204; H01L 27/3244; H01L 27/1214

(57) ABSTRACT

This application provides a display panel. The display panel includes: an array substrate, having an outer surface; a color-filter substrate, disposed opposite to the array substrate; and an anti-electrostatic thin film, disposed on the outer surface of the array substrate. The anti-electrostatic thin film covers the outer surface of the array substrate.

### BACKGROUND

### Technical Field

This application relates to the display field, and in particular, to a display panel having an anti-electrostatic thin film.

### Related Art

With development of information technologies, a display panel and a display apparatus, as important carriers for information presentation, attract more and more attention of manufacturers in various fields. However, at the same time, higher requirements are also proposed on display panels and display apparatuses. Some products have very high anti-electrostatic requirements because of high sensitivity.

A thin-film transistor liquid-crystal display (TFT-LCD), as one type of display apparatus, has been widely applied due to good chromatic characteristics and features such as lightweight and convenience. During production and manufacturing of TFT-LCDs, film layers having different functions are coated on an array substrate, and different film layers are finished in different mechanical devices and reaction chambers, and a great amount of electrostatic charges are generated unavoidably when the film layers are coated and the substrate is moved. The electrostatic charges are accumulated on the array substrate and generate a large potential difference when the array substrate is in contact with a transmission device, resulting in puncturing a film layer near a contact point and seriously affecting the quality of the display panel or display apparatus.

### SUMMARY

To resolve the foregoing technical problem, an objective of this application is to provide a display panel. An anti-electrostatic thin film is disposed on an array substrate, to disperse and export static electricity generated when the array substrate is in contact with a machine during a process of manufacturing a panel and prevent the display panel from being scratched when the display panel is moved, thereby enhancing quality and a yield of a product.

To achieve the objective of this application and resolve the technical problem, the following technical solution is used. The objective of this application is to provide a display panel, comprising: an array substrate, having an outer surface, a color-filter substrate, disposed opposite to the array substrate; and an anti-electrostatic thin film, disposed on the outer surface of the array substrate. The anti-electrostatic thin film covers the outer surface of the array substrate.

In an embodiment of this application, the anti-electrostatic thin film extends from the outer surface of the array substrate and at least one side of a side edge of the array substrate is covered by the anti-electrostatic thin film.

In an embodiment of this application, the anti-electrostatic thin film extends from the outer surface of the array substrate and is attached to the side edge of the array substrate.

In an embodiment of this application, the anti-electrostatic thin film extends from the outer surface of the array substrate and covers the side edge of the array substrate.

In an embodiment of this application, the anti-electrostatic thin film is an insulating thin film.

In an embodiment of this application, the anti-electrostatic thin film is a conductive thin film.

In an embodiment of this application, the conductive thin film is configured to be grounded.

In an embodiment of this application, the anti-electrostatic thin film is disposed on the outer surface of the array substrate by means of attachment.

In an embodiment of this application, the anti-electrostatic thin film is disposed on the outer surface of the array substrate by means of physical vapor deposition.

In an embodiment of this application, the anti-electrostatic thin film is disposed on the outer surface of the array substrate by means of chemical vapor deposition.

In an embodiment of this application, the outer surface of the array substrate is far away from the color-filter substrate.

Another objective of this application is to provide a display panel, comprising: an array substrate, having an outer surface; a color-filter substrate, disposed opposite to the array substrate; and an anti-electrostatic thin film, disposed on the outer surface of the array substrate. The anti-electrostatic thin film is an insulating thin film or a conductive thin film. The anti-electrostatic thin film covers the outer surface of the array substrate.

In this application, an anti-electrostatic thin film is disposed on an array substrate, to disperse and export static electricity generated when the array substrate is in contact with a machine during a process of manufacturing a panel and prevent a display panel from being scratched when the display panel is moved, thereby enhancing quality and a yield of a product.

### BRIEF DESCRIPTION OF THE DRAWINGS

FIG. 1 is a schematic diagram of an exemplary display panel;

FIG. 2 is a schematic diagram of steps of a process of manufacturing a display panel according to an embodiment of this application;

FIG. 3 is a schematic diagram of a display panel according to an embodiment of this application;

FIG. 4 is a schematic diagram of a display panel according to yet another embodiment of this application;

FIG. 5 is a schematic diagram of a display panel according to still another embodiment of this application; and

FIG. 6 is a schematic diagram of a display panel according to another embodiment of this application.

### DETAILED DESCRIPTION

The following embodiments are described with reference to the accompanying drawings, which are used to exemplify specific embodiments for implementation of this application. Terms about directions mentioned in this application, such as “on”, “below”, “front”, “back”, “left”, “right”, “in”, “out”, and “side surface” merely refer to directions in the accompanying drawings. Therefore, the used terms about directions are used to describe and understand this application, and are not intended to limit this application.

The accompanying drawings and the description are considered to be essentially exemplary, rather than limitative. In the figures, units with similar structures are represented by using the same reference number. In addition, for understanding and ease of description, the size and the thickness of each component shown in the accompanying drawings are arbitrarily shown, but this application is not limited thereto.

In the accompanying drawings, for clarity, thicknesses of a layer, a film, a panel, an area, and the like are enlarged. In the accompanying drawings, for understanding and ease of description, thicknesses of some layers and areas are enlarged. It should be understood that when a component such as a layer, a film, an area, or a base is described to be “on” “another component”, the component may be directly on the another component, or there may be an intermediate component.

In addition, throughout this specification, unless otherwise explicitly described to have an opposite meaning, the word “include” is understood as including the component, but not excluding any other component. In addition, throughout the specification, “on” means that one is located above or below a target component and does not necessarily mean that one is located on the top based on a gravity direction.

To further describe the technical measures taken in this application to achieve the intended application objective and effects thereof, specific implementations, structures, features, and effects of a display panel that are provided according to this application are described below in detail with reference to the accompanying drawings and specific embodiments.

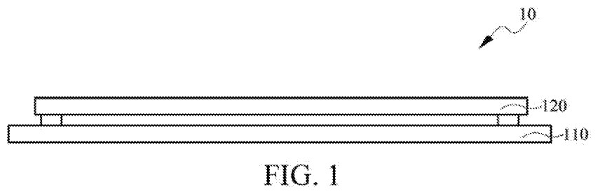

FIG. 1 is a schematic diagram of an exemplary display panel. Referring to FIG. 1, an exemplary display panel 10 includes an array substrate 110 and a color-filter substrate 120 disposed opposite to the array substrate 110. A plurality of film layers, for example, a gate layer, a gate insulating layer, a drain layer, and a source layer, is coated on the array substrate 110, and the different layers are coated in different reaction chambers because of requiring different raw materials, temperatures, and pH values. The array substrate 110 and the color-filter substrate 120 are delivered to different reaction chambers through transmission devices such as a conveyor belt and a mechanical arm, and during this process, the substrate is in contact with the devices and a large amount of electrostatic charges are accumulated on a part of the substrate near a contact point, and the accumulation of the electrostatic charges causes a potential difference formed between the contact point and the film layers on the substrate. When reaching a critical value/threshold, the potential difference punctures the film layer near the contact point, causing an irreparable damage to the substrate, reducing the quality of a product, and affecting goodness and yield of the product.

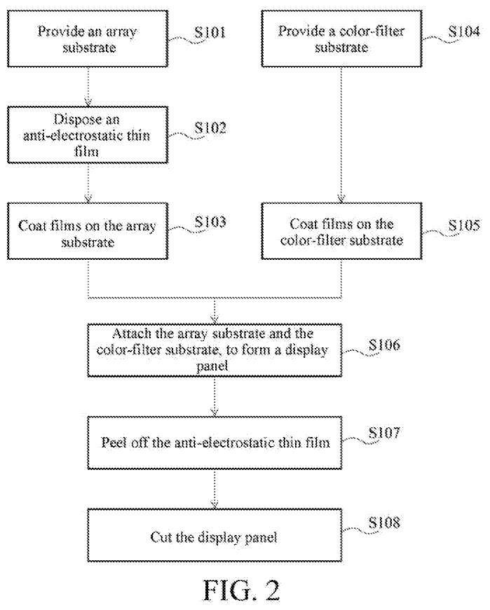

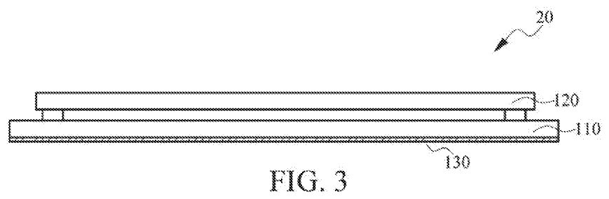

FIG. 2 is a schematic diagram of steps of a process of manufacturing a display panel according to an embodiment of this application, and FIG. 3 is a schematic diagram of a display panel according to an embodiment of this application. Referring to FIG. 2 and FIG. 3, in an embodiment of this application, a method for manufacturing a display panel includes the following steps.

Step S101: Provide an array substrate.

Step S102: Dispose an anti-electrostatic thin film; dispose the anti-electrostatic thin film on an outer surface of the array substrate. The anti-electrostatic thin film covers the outer surface of the array substrate.

Step S103: Coat films on the array substrate; coat each film layer and member required by the display panel, such as an active switch and a pixel electrode layer, on another surface of the array substrate.

Step S104: Provide a color-filter substrate.

Step S105: Coat films on the color-filter substrate, and coat film layer members such as a black matrix and a common electrode layer on a surface of the color-filter substrate.

Step S106: Attach the array substrate and the color-filter substrate, to form a display panel.

Step S107: Peel off the anti-electrostatic thin film.

Step S108: Cut the display panel; cut the display panel into a required size.

In an embodiment of this application, the anti-electrostatic thin film is an insulating thin film or a conductive thin film, and can be directly attached as a thin film sheet, or disposed on the outer surface of the array substrate by means of physical vapor deposition or chemical vapor deposition.

In an embodiment of this application, the anti-electrostatic thin film is an insulating thin film made of glass or polyethylene glycol terephthalate, to avoid the possibility of accumulating electrostatic charges.

In an embodiment of this application, the anti-electrostatic thin film is a thin film made of indium, tin, zinc, and compounds thereof, and for example, is a conductive thin film made of indium tin oxide (ITO), indium zinc oxide (IZO), or aluminum doped zinc oxide (AZO). The conductive thin film is configured to be grounded, can export electrostatic charges in time, avoiding forming a large potential difference and further preventing the potential difference from puncturing a film layer.

In an embodiment of this application, the anti-electrostatic thin film is a dense insulating thin film or a passivation thin film made of aluminum, silicon, and oxides thereof.

In an embodiment of this application, the anti-electrostatic thin film can be peeled off by being torn directly (if the anti-electrostatic thin film is an attached thin film sheet), or by being rinsed and removed by using a chemical reagent (if the anti-electrostatic thin film is formed by means of physical vapor deposition or chemical vapor deposition).

FIG. 3 is a schematic diagram of a display panel according to an embodiment of this application. Referring to FIG. 3, in an embodiment of this application, a display panel 20 manufactured by using the foregoing embodiment includes: an array substrate 110, having an outer surface; a color-filter substrate 120, disposed opposite to the array substrate 110; and an anti-electrostatic thin film 130, disposed on the outer surface of the array substrate 110. The anti-electrostatic thin film 130 is an insulating thin film or a conductive thin film. The anti-electrostatic thin film 130 covers the outer surface of the array substrate 110.

In an embodiment of this application, the outer surface of the array substrate 110 is far away from the color-filter substrate 120.

In an embodiment of this application, the anti-electrostatic thin film 130 can be attached as a thin film sheet, or disposed on the outer surface of the array substrate 110 by means of physical vapor deposition or chemical vapor deposition.

In an embodiment of this application, the anti-electrostatic thin film 130 is an insulating thin film made of glass or polyethylene glycol terephthalate, to avoid the possibility of accumulating electrostatic charges.

In an embodiment of this application, the anti-electrostatic thin film 130 is a thin film made of indium, tin, zinc, and compounds thereof, and for example, is a conductive thin film made of ITO, IZO, or AZO. The conductive thin film 130 is configured to be grounded, and can export electrostatic charges in time, avoiding forming a large potential difference and further preventing the potential difference from puncturing a film layer.

In an embodiment of this application, the anti-electrostatic thin film 130 is a dense insulating thin film or a passivation thin film made of aluminum, silicon, and oxides thereof.

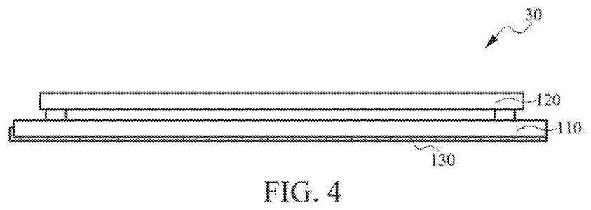

FIG. 4 is a schematic diagram of a display panel according to yet another embodiment of this application. Referring to FIG. 4, in an embodiment of this application, compared with the display panel 20, a display panel 30 includes an anti-electrostatic thin film 130. The anti-electrostatic thin film 130 covers an outer surface of an array substrate 110, and extends toward a side edge of the array substrate 110. At least one side of the side edge of the array substrate 110 is covered by the anti-electrostatic thin film 130.

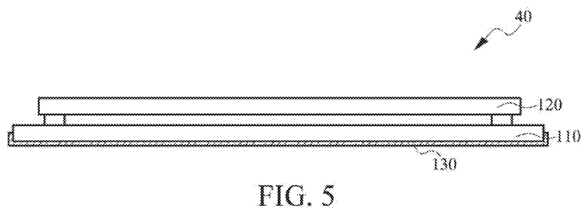

FIG. 5 is a schematic diagram of a display panel according to still another embodiment of this application. Referring to FIG. 5, in an embodiment of this application, compared with the display panels (20 and 30), a display panel 40 includes an anti-electrostatic thin film 130. The anti-electrostatic thin film 130 covers an outer surface of an array substrate 110, and extends toward a side edge of the array substrate 110. The anti-electrostatic thin film 130 extends and is attached to the side edge of the array substrate 110.

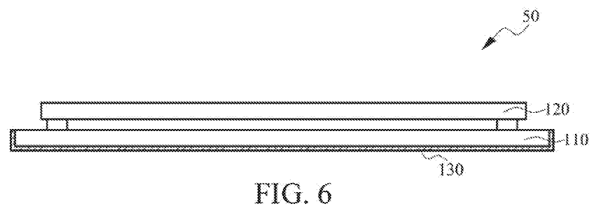

FIG. 6 is a schematic diagram of a display panel according to another embodiment of this application. Referring to FIG. 6, in an embodiment of this application, compared with the display panels (20, 30 and 40), a display panel 50 includes an anti-electrostatic thin film 130. The anti-electrostatic thin film 130 covers an outer surface of an array substrate 110, and extends toward a side edge of the array substrate 110. The anti-electrostatic thin film 130 extends toward the side edge of the array substrate 110, and covers and attaches to the side edge of the array substrate 110.

In some embodiments, the anti-electrostatic thin film 130 is disposed on the outer surface of the array substrate 110 and is in contact with a conveying device during transportation, thereby reducing or eliminating the possibility of scratching the array substrate 110 during transportation and enhancing a yield of the process.

In some embodiments, the anti-electrostatic thin film 130 can alternatively be disposed on the outer surface of the color-filter substrate 120, thereby achieving anti-electrostatic and scratch proof possibility.

In some embodiments, when the array substrate 110 and the color-filter substrate 120 are attached to form a display panel, that is, after the former process is finished, the anti-electrostatic thin film 130 is peeled off.

Referring to FIG. 3 to FIG. 6 again, in some embodiments, the display panel formed by attaching the array substrate 110 and the color-filter substrate 120 may be, for example, a twisted nematic (TN) liquid display panel, a super twisted nematic (STN) liquid display panel, or an optically compensated birefringence (OCB) liquid display panel, but the present invention is not limited thereto. The anti-electrostatic thin film 130 can also be used in an organic light emitting diode (OLED) display panel, a quantum-dot light emitting diode (QLED) display panel, a curved display panel, and a plasma display panel.

In this application, the anti-electrostatic thin film 130 is disposed on the array substrate 110, to disperse and export static electricity generated when the array substrate is in contact with a conveying machine during a process of manufacturing a substrate and a panel. In addition, the anti-electrostatic thin film 13 can prevent the substrate and the panel from being scratched during transportation, thereby improving the quality and yield of the product.

The wordings such as “in some embodiments” and “in various embodiments” are repeatedly used. The wordings usually refer to different embodiments, but they may also refer to a same embodiment. The words, such as “comprise”, “have”, and “include”, are synonyms, unless other meanings are indicated in the context thereof.

The foregoing descriptions are merely preferred embodiments of this application, and are not intended to limit this application in any form. Although this application has been disclosed above through the preferred embodiments, the embodiments are not intended to limit this application. Any person skilled in the art can make some variations or modifications, which are equivalent changes, according to the foregoing disclosed technical content to obtain equivalent embodiments without departing from the scope of the technical solutions of this application. Any simple amendment, equivalent change, or modification made to the foregoing embodiments according to the technical essence of this application without departing from the content of the technical solutions of this application shall fall within the scope of the technical solutions of this application.

What is claimed is:

1. A display panel, comprising:
an array substrate, having an outer surface;
a color-filter substrate, disposed opposite to the array substrate; and
an anti-electrostatic thin film, disposed on the outer surface of the array substrate, wherein
the anti-electrostatic thin film covers the outer surface of the array substrate.

2. The display panel according to claim 1, wherein the anti-electrostatic thin film extends from the outer surface of the array substrate.

3. The display panel according to claim 2, wherein at least one side of a side edge of the array substrate is covered by the anti-electrostatic thin film.

4. The display panel according to claim 2, wherein the anti-electrostatic thin film extends from the outer surface of the array substrate and is attached to a side edge of the array substrate.

5. The display panel according to claim 2, wherein the anti-electrostatic thin film extends from the outer surface of the array substrate, and covers a side edge of the array substrate.

6. The display panel according to claim 1, wherein the anti-electrostatic thin film is an insulating thin film.

7. The display panel according to claim 6, wherein the anti-electrostatic thin film is a dense insulating thin film.

8. The display panel according to claim 1, wherein the anti-electrostatic thin film is a conductive thin film.

9. The display panel according to claim 8, wherein the conductive thin film is configured to be grounded.

10. The display panel according to claim 1, wherein the anti-electrostatic thin film is a passivation thin film.

11. The display panel according to claim 1, wherein the anti-electrostatic thin film is glass.

12. The display panel according to claim 1, wherein the anti-electrostatic thin film is disposed on the outer surface of the array substrate by means of attachment.

13. The display panel according to claim 1, wherein the anti-electrostatic thin film is disposed on the outer surface of the array substrate by means of physical vapor deposition.

14. The display panel according to claim 1, wherein the anti-electrostatic thin film is disposed on the outer surface of the array substrate by means of chemical vapor deposition.

15. The display panel according to claim 1, wherein the outer surface of the array substrate is far away from the color-filter substrate.

16. A display panel, comprising:
an array substrate, having an outer surface;
a color-filter substrate, disposed opposite to the array substrate; and
an anti-electrostatic thin film, disposed on the outer surface of the array substrate, wherein
the anti-electrostatic thin film is an insulating thin film or a conductive thin film; and
the anti-electrostatic thin film covers the outer surface of the array substrate.

17. The display panel according to claim 16, wherein the anti-electrostatic thin film extends from the outer surface of the array substrate.

18. The display panel according to claim 16, wherein the anti-electrostatic thin film is a dense insulating thin film.

19. The display panel according to claim 16, wherein the conductive thin film is configured to be grounded.

20. The display panel according to claim 16, wherein the anti-electrostatic thin film is a passivation thin film.
